(19) United States
(12) Patent Application Publication
(10) Pub. No.: US 2025/0299924 A1
(43) Pub. Date: Sep. 25, 2025

(54) SUBSTRATE PROCESSING METHOD AND SUBSTRATE PROCESSING APPARATUS

(71) Applicant: Tokyo Electron Limited, Tokyo (JP)

(72) Inventors: Takafumi NOGAMI, Yamanashi (JP); Kenichi KOTE, Yamanashi (JP)

(21) Appl. No.: 19/232,127

(22) Filed: Jun. 9, 2025

Related U.S. Application Data
(63) Continuation of application No. PCT/JP2023/043685, filed on Dec. 6, 2023.

(30) Foreign Application Priority Data
Dec. 20, 2022 (JP) 2022-203725

(51) Int. Cl. H01J 37/32; C23C 16/34; C23C 16/458; C23C 16/511; C23C 16/52; C23C 16/56

(52) U.S. Cl. CPC H01J 37/32302; C23C 16/345; C23C 16/4583; C23C 16/511; C23C 16/52; C23C 16/56; H01J 2237/332

(57) ABSTRACT

A substrate processing method for modifying a film formed on a substrate is provided. The method includes: forming a precoated film on the surface of a processing chamber by a plasma formed from a precoating gas using a microwave having a first power; preparing the substrate on a mounting table in the processing chamber; and modifying the film by irradiating the film with a hydrogen-containing plasma formed from a hydrogen-containing gas using a microwave having a second power lower than the first power.

### CROSS-REFERENCE TO RELATED APPLICATIONS

This application is a continuation application of International Application No. PCT/JP2023/043685, filed on Dec. 6, 2023, and designating the U.S., which is based upon and claims priority to Japanese Patent Application No. 2022-203725, filed on Dec. 20, 2022, the entire contents of which are incorporated herein by reference.

### BACKGROUND

### Technical Field

The present disclosure relates to a substrate processing method and a substrate processing apparatus.

### Background Art

For example, Japanese Patent Application Laid-Open Publication No. 2017-224669 proposes a method for processing a silicon nitride film formed on a substrate by plasma CVD, wherein the method irradiates the silicon nitride film with a microwave plasma, to remove hydrogen on the surface of the silicon nitride film by atomic hydrogen in the microwave plasma, and modify the surface of the silicon nitride film.

### SUMMARY

According to one aspect of the present disclosure, a substrate processing method for modifying a film formed on a substrate includes: forming a precoated film on a surface of a processing chamber by a plasma formed from a precoating gas using a microwave having a first power; preparing the substrate on a mounting table in the processing chamber; and modifying the film by irradiating the film with a hydrogen-containing plasma formed from a hydrogen-containing gas using a microwave having a second power that is lower than the first power.

### BRIEF DESCRIPTION OF THE DRAWINGS

FIG. 1 is a cross-sectional schematic view showing an example of a plasma processing apparatus according to an embodiment;

FIG. 2 is a flowchart showing an example of a substrate processing method according to the embodiment;

FIG. 3 is a diagram showing an example of the relationship between the microwave power and the number of particles during hydrogen modification according to the embodiment;

FIG. 4 is a diagram showing an example of the relationship between the microwave power and metal contamination depending on presence or absence of precoated film formation according to the embodiment;

FIG. 5A is a diagram showing an example of the dependency of the number of particles during hydrogen modification on the number of wafers processed according to the embodiment;

FIG. 5B is a diagram showing an example of the dependency of the number of particles during hydrogen modification on the processing time according to the embodiment;

FIG. 6A is a diagram showing an example of a type of a hydrogen modification-target film and the effect of hydrogen modification according to the embodiment;

FIG. 6B is a diagram showing an example of a type of a hydrogen modification-target film and the effect of hydrogen modification according to the embodiment; and

FIG. 6C is a diagram showing an example of a type of a hydrogen modification-target film and the effect of hydrogen modification according to the embodiment.

### DETAILED DESCRIPTION OF THE DISCLOSURE

Embodiments of the present disclosure will be described below with reference to the drawings. In the drawings, the same components are denoted by the same reference numerals, and duplicate descriptions may be omitted.

In this specification, the directions, such as parallel, right-angled, orthogonal, horizontal, perpendicular, vertical, and lateral directions and the like are allowed errors to the extent that they do not impair the effect of the embodiment. The shape of the corners is not limited to a right-angled shape, and may be rounded in an arcuate shape. Being parallel, right-angled, orthogonal, horizontal, perpendicular, circular, and coincident may include being substantially parallel, substantially right-angled, substantially orthogonal, substantially horizontal, substantially perpendicular, substantially circular, and substantially coincident.

### [Plasma Processing Apparatus]

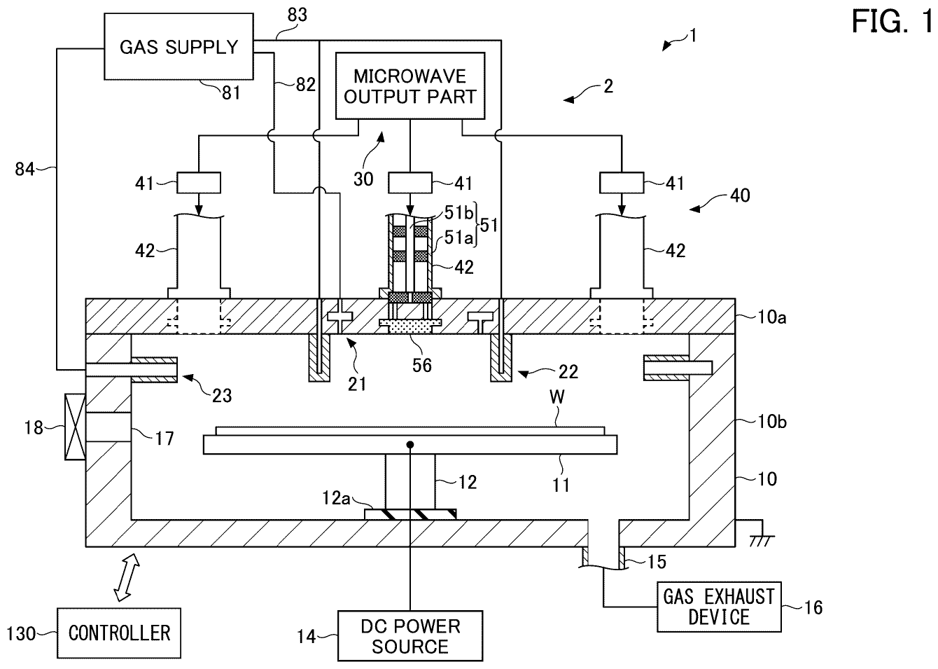

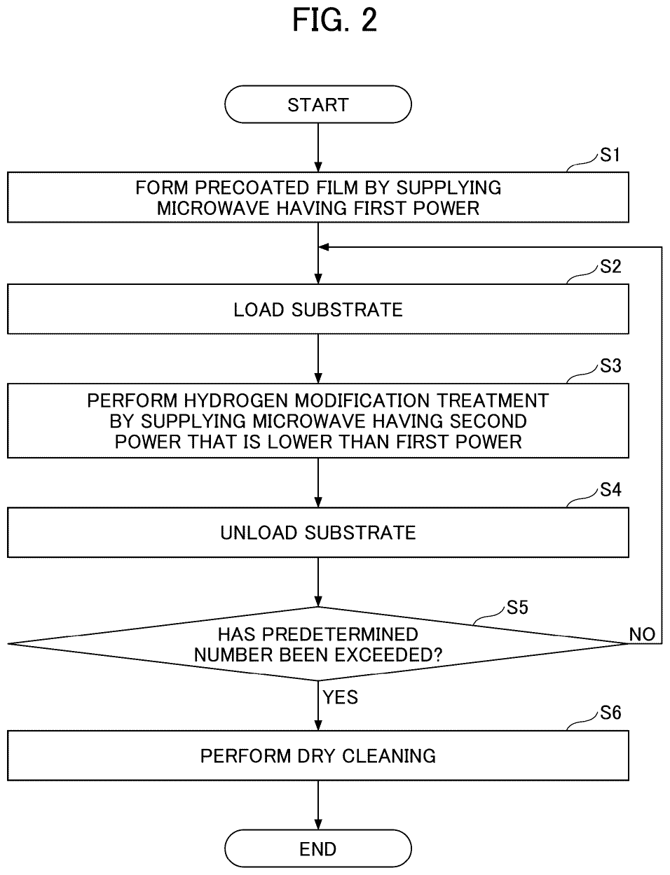

A configuration example of a substrate processing apparatus according to one embodiment will be described with reference to FIG. 1. FIG. 1 is a schematic cross-sectional view showing an example of a plasma processing apparatus 1 according to one embodiment. The plasma processing apparatus 1 is an example of a substrate processing apparatus for performing a substrate processing method according to one embodiment (see FIG. 2) described later.

The plasma processing apparatus 1 includes a processing chamber 10 and a plasma source 2. The processing chamber 10 has a substantially cylindrical airtight shape made of a material, such as aluminum or the like, and is grounded. The plasma source 2 introduces microwaves of a predetermined power into the processing chamber 10 to form a surface wave plasma. A top wall 10a of the processing chamber 10 is formed of a main body made of a metal that is fitted with dielectric members (hereinafter, referred to as dielectric windows 56) of a plurality of microwave radiation mechanisms 42. Thus, the plasma source 2 introduces microwaves into the processing chamber 10 via the plurality of dielectric windows 56 in the top wall 10a.

The plasma processing apparatus 1 includes a controller 130. The controller 130 is, for example, a computer and includes a program storage unit (not shown). The program storage unit stores a program for controlling the processing of a substrate W, an example of which is a semiconductor wafer, in the plasma processing apparatus 1. The program may have been recorded in a computer-readable storage medium, such as a computer-readable hard disk (HD), flexible disk (FD), compact disk (CD), magneto-optical (MO) disk, memory card, and the like, and installed in the controller 130 from the storage medium.

In the processing chamber 10, a mounting table 11 for supporting the substrate W horizontally is supported in the center of the bottom of the processing chamber 10 by a cylindrical supporting member 12 via an insulating member 12a. The material of the mounting table 11 and the supporting member 12 is, for example, a metal, such as aluminum whose surface is subjected to anodization (anodic oxidation), or an insulating material (such as ceramics) having an electrode for high-frequency radiation inside.

Although not shown, the mounting table 11 is provided with a temperature control mechanism, a gas flow path for supplying a gas for heat transfer to the back surface of the substrate W, pins for moving the substrate W up or down, and the like. Furthermore, an electrostatic chuck for electrosorption of the substrate W may be provided.

A DC power source 14 is connected to the mounting table 11. When a DC voltage is supplied from the DC power source 14 to the mounting table 11, ions in a plasma are attracted to the substrate W side, which contributes to film quality improvement and in-plane uniformity of substrate W processing. A high-frequency power source may be connected instead of the DC power source 14. The DC power source 14 and the high-frequency power source do not need to be connected.

A gas exhaust pipe 15 is connected to the bottom of the processing chamber 10, and a gas exhaust device 16 including a vacuum pump is connected to the gas exhaust pipe 15. By operating the gas exhaust device 16, it is possible to exhaust the interior of the processing chamber 10 of gas, and to reduce the interior of the processing chamber 10 to a predetermined pressure. A side wall 10b of the processing chamber 10 is provided with a loading/unloading port 17 for loading or unloading the substrate W, and a gate valve 18 for opening and closing the loading/unloading port 17.

The plasma processing apparatus 1 includes a first gas shower part 21 for discharging a predetermined gas from the top wall 10a of the processing chamber 10 into the processing chamber 10, and a second gas shower part 22 for introducing gas from a position between the top wall 10a and the mounting table 11. Furthermore, the plasma processing apparatus 1 includes a third gas shower part 23 for introducing gas from a position in the processing chamber 10 that is between the top wall 10a and the mounting table 11 and is on the outer side of the second gas shower part 22.

In FIG. 1, although the first gas shower part 21 and the second gas shower part 22 are shown at positions different in the radial direction for the sake of convenience, they are provided alternately on the same circle. The first gas shower part 21 is provided on the top wall 10a of the processing chamber 10, and supplies, from a first position, gas carried thereto from a gas supply 81 through a gas line 82. The second gas shower part 22 is provided on the top wall 10a of the processing chamber 10, and supplies, from a second position lower than the first position, gas carried thereto from the gas supply 81 through a gas line 83. The third gas shower part 23 is provided on the side wall 10b of the processing chamber 10, and supplies, from a third position lower than the first position, gas carried thereto from the gas supply 81 through a gas line 84.

In the formation of a precoated film (e.g., an SiN film) in a substrate processing method described later, a silicon raw material gas may be supplied from the second gas shower part 22 and the third gas shower part 23. Examples of the silicon raw material gas include silane (SiH₄) gas, dichlorosilane (DCS) gas, and the like. A reactive gas (nitride gas) may be supplied from the first gas shower part 21, the second gas shower part 22, and the third gas shower part 23. Examples of the nitride gas include a gas containing at least one of N₂ gas, NH₃ gas, or mixed gas of N₂ and H₂, and the like.

The silicon raw material gas may be supplied from at least one of the second gas shower part 22 or the third gas shower part 23. By supplying the silicon raw material gas from the second position and/or the third position that are lower than the first position of the first gas shower part 21, it is possible to inhibit excessive dissociation of the silicon raw material gas.

Gases other than the silicon raw material gas (e.g., helium (He) gas) may be supplied from at least one of the first gas shower part 21, the second gas shower part 22, or the third gas shower part 23. The helium gas functions as a plasma forming gas (ignition gas) and a diluent gas. Instead of the helium gas, argon (Ar) gas or a mixed gas of argon gas and helium gas may be supplied. The helium gas may be merged with the silicon raw material gas at the outlet of a gas box, not shown, and supplied into the processing chamber 10 from each gas shower part. The plasma forming gas and the diluent gas do not need to be supplied.

In the hydrogen modification in the substrate processing method described later, hydrogen (H₂) gas and argon (Ar) gas are supplied from at least one of the first gas shower part 21, the second gas shower part 22, or the third gas shower part 23. In the hydrogen modification, the gas to be supplied may be either or both of hydrogen gas and ammonia (NH₃) gas.

The plasma source 2 has a microwave output part 30 for outputting a microwave by distributing them to a plurality of paths, and a microwave propagating part 40 for propagating the microwave output from the microwave output part 30.

The microwave output part 30 includes a microwave power source, a microwave oscillator, an amplifier, and a distributor. The microwave power source supplies power to the microwave oscillator. The microwave oscillator causes, for example, PLL oscillation of a microwave having a predetermined frequency (e.g., 860 MHz). The amplifier amplifies the oscillated microwave. The distributor distributes the microwave amplified by the amplifier while managing impedance matching between the input side and the output side so as to minimize the loss of the microwave. As the frequency of the microwave, in addition to 860 MHz, various frequencies in the range of 700 MHz to 3 GHz, such as 915 MHz and the like, can be used.

The microwave propagating part 40 includes a plurality of amplifier parts 41 and a plurality of microwave radiation mechanisms 42 provided correspondingly to the amplifier parts 41. A total of seven microwave radiation mechanisms 42 are provided, namely, for example, one in the center of the top wall 10a and six at equal intervals on the circumference of a circle centering on the center one. In this example, they are arranged such that the distance between the center microwave radiation mechanism 42 and the microwave radiation mechanisms 42 on the outer circumference is equal to the distance between the microwave radiation mechanisms 42 on the outer circumference.

The amplifier parts 41 amplify the microwave distributed by the distributor and guide it to the corresponding microwave radiation mechanisms 42. The microwave radiation mechanisms 42 each include a coaxial tube 51. The coaxial tube 51 has a coaxial microwave propagation path composed of a cylindrical outer conductor 51a and a rod-shaped inner conductor 51b provided in the center thereof. The microwave radiation mechanisms 42 each include a power feeding antenna (not shown) for feeding the microwave amplified by the amplifier part 41 to the coaxial tube 51. Furthermore, the microwave radiation mechanisms 42 each include a tuner for matching the impedance of a load with the characteristic impedance of the microwave power source, and an antenna part for radiating the microwave from the coaxial tube into the processing chamber 10.

The antenna part is provided at the lower end of the coaxial tube 51 and is fitted into the metal part of the top wall 10a of the processing chamber 10. The antenna part includes the dielectric window 56, and the microwave transmitted through the dielectric window 56 forms a surface wave plasma in a region directly under the dielectric window 56 in the processing chamber 10.

A plurality of plasma sources 2 (dielectric windows 56) are provided, namely one in the center of the ceiling part and six in the outer periphery part of the ceiling part. The plurality of plasma sources 2 (dielectric windows 56) can independently control the microwave powers to be supplied from the plasma sources 2 themselves, respectively. The microwave powers to be supplied from the plasma sources 2 (dielectric windows 56) in the outer periphery part may be higher than, lower than, or the same as the microwave power to be supplied from the plasma source 2 in the center.

In the substrate processing method according to an embodiment described later, a film formed on a substrate by at least one of a thermal Chemical Vapor Deposition (CVD) apparatus or a plasma CVD apparatus is loaded into the plasma processing apparatus 1, to modify the film with a hydrogen-containing plasma.

The film formed on the substrate may be formed by a thermal Atomic Layer Deposition (ALD) apparatus or a plasma ALD apparatus. The film formed on the substrate may be a silicon-containing film or a carbon film. Specifically, the silicon-containing film may be any of an SiN film, an SiCN film, an SiOCN film, an SiON film, an SiO₂ film, or a silicon film. The carbon film may be an amorphous carbon film.

In the plasma processing apparatus 1 having such a configuration, before modifying the film formed on the substrate W with a hydrogen-containing plasma, a precoated film is formed on the surface of the processing chamber 10 by a plasma formed from a precoating gas using a microwave having a first power in a state in which the target substrate W is not present in the processing chamber 10.

In the substrate processing method according to one embodiment, after a precoated film is formed on the surface of the processing chamber 10, the substrate W is loaded in and placed on the mounting table 11, and the surface layer of the film is modified by irradiation of the film with a hydrogen-containing plasma formed from a hydrogen-containing gas using a microwave having a second power.

In the substrate processing method according to one embodiment, the microwave having the second power is lower than the microwave having the first power. Thus, it is possible to suppress particles during microwave plasma modification of the film formed on the substrate. Hereinafter, the substrate processing method according to the present embodiment will be specifically described regarding an example in which the film formed on the substrate is an SiN film.

### [Substrate Processing Method]

A substrate processing method according to an embodiment will be described below with reference to FIG. 2. FIG. 2 is a flowchart showing an example of a substrate processing method according to an embodiment. The substrate processing method according to an embodiment is controlled by the controller 130 and performed by the plasma processing apparatus 1.

First, in step S1, the controller 130 supplies a microwave having the first power into the processing chamber 10, to form a precoated film on the surface of the processing chamber 10 by a plasma formed from a precoating gas using the microwave having the first power.

The precoating gas includes a silicon raw material gas and a reactive gas reacting with the silicon raw material gas. By exposing the internal surface of the processing chamber 10 to the plasma formed by supplying the silicon raw material gas and the reactive gas, a precoated film is formed on the surface of the processing chamber 10. The precoated film is preferably an SiN film regardless of the type of the film to be modified with a hydrogen-containing plasma, which will be described later. An example of process conditions for forming a precoated film in a case of forming an SiN film as a precoated film on the surface of the processing chamber 10 is shown below.

### <Process Conditions for Forming Precoated Film (SiN Film)>

### Types of Gases

Silicon raw material gas: Silane (SiH₄) gas
Reactive gas: Nitrogen (N₂) gas or ammonia (NH₃) gas
Other gases: Helium (He) gas
Pressure in the processing chamber: 6 Pa to 133 Pa
Microwave power (first power): 2,000 W to 6,000 W

However, the above process conditions are an example and are not limited thereto. In addition to being within the above range, it is only needed that the first power is higher than the second power, which is the microwave power for modification of a film with a hydrogen-containing plasma (hereinafter, also referred to as “hydrogen modification”).

After the formation of the precoated film, continuous hydrogen modification processing is performed on a specified number of substrates. Specifically, in step S2, the controller 130 loads a substrate W on which the film to be modified is formed into the processing chamber 10, and prepares it by placing it on the mounting table 11.

Next, in step S3, the controller 130 supplies a hydrogen-containing gas, supplies a microwave having the second power that is lower than the first power into the processing chamber 10, and irradiates the film (an SiN film in this embodiment) on the substrate W with a hydrogen-containing plasma, which is a microwave plasma formed from the hydrogen-containing gas using the microwave having the second power, to modify the film. An example of process conditions for hydrogen modification is shown below.

### <Process Conditions for Hydrogen Modification>

### Types of Gases

Hydrogen-containing gas: Hydrogen (H₂) gas Argon (Ar) gas
Pressure in the processing chamber: 2 Pa to 133 Pa
Microwave power (second power): 100 W to 4,000 W

However, the above process conditions are an example and are not limited thereto. For example, the hydrogen-containing gas needs only to contain hydrogen gas and inert gas. The hydrogen-containing gas may be either or both of hydrogen gas and ammonia gas. Therefore, the hydrogen-containing gas may contain helium gas, neon gas, krypton gas, xenon gas, or the like as the inert gas other than argon gas.

The process conditions for hydrogen modification can be used regardless of the type of the film formed on the substrate W. However, in the case where the film formed on the substrate W is an SiN film, the effect of improving the film quality by hydrogen modification of the SiN film can be expected when the film density of the SiN film is low (for example, 2.7 (g/cm³) or less).

A microwave plasma (hydrogen-containing plasma) is a plasma having a low electron temperature but having a high electron density. Therefore, when irradiating the SiN film with the hydrogen-containing plasma, the hydrogen-containing plasma excited by the microwave contains hydrogen radicals and hydrogen ions, which makes it possible to suppress the energy of ions in the plasma to be low, and to suppress the value of the energy to be lower than the Si—N bond energy. Therefore, by irradiating the SiN film with the hydrogen-containing plasma, it is possible to cause mainly hydrogen radicals in the plasma to remove H as H₂ from the Si—H bond in the film without destroying the Si—N bond in the surface part of the SiN film. Thus, the SiN film can be modified to a state with a low hydrogen content, and the film density can be increased. By modifying the SiN film in this way, it is possible to adjust the film density to a high film density (e.g., 2.7 (g/cm³) or greater), and to impart a desired characteristic (e.g., a high etching selectivity for wet etching and dry etching).

In particular, when the film on the substrate W is for use as a hard mask, it is possible to obtain a film having a high resistance (etching selectivity) for wet etching and dry etching, which is required of a hard mask.

Next, in step S4, the controller 130 unloads the substrate W, after being subjected to hydrogen modification, from the processing chamber 10.

Next, in step S5, the controller 130 determines whether the number of substrates subjected to the hydrogen modification process exceeds a predetermined number that is previously set. When determining that the number of substrates subjected to hydrogen modification does not exceed the predetermined number, the controller 130 returns to step S2, loads the next substrate W, proceeds to step S3, and performs the hydrogen modification process of step S3 on the next substrate W.

When the hydrogen modification process is continuously performed on more than the predetermined number of substrates W, the precoated film is damaged due to the impingement of ions in the plasma, and the like, and peels off during hydrogen modification to generate particles. Therefore, the predetermined number in step S5 is predetermined to be a specific number to arrange for cleaning to be performed and a precoated film to be formed again, before the precoated film peels off and particles are generated.

In step S5, when determining that the number of substrates subjected to the hydrogen modification process has exceeded the specified number, the controller 130 moves forward to step S6, to perform dry cleaning and remove the entirety of the precoated film, and ends this process.

That is, when the number of substrates subjected to the hydrogen modification process has exceeded the specified number of substrates (step S5), hydrogen modification (steps S2 and S3) on the next substrate W is performed after the re-formation of a precoated film on the surface of the processing chamber 10 (step S1), which is performed after the dry cleaning process (step S6).

### [Result of Experiment 1]

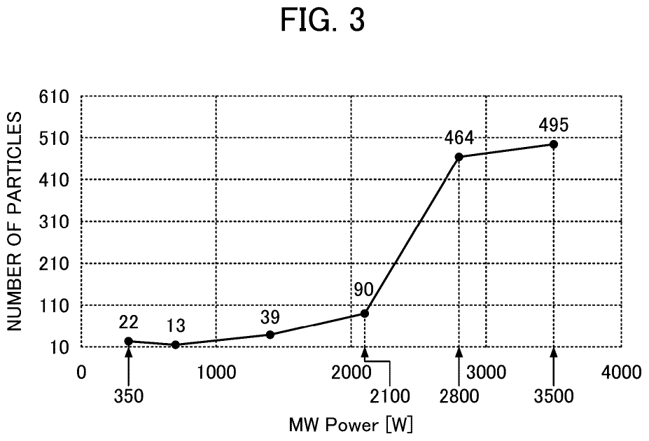

The result of Experiment 1 on the number of particles during hydrogen modification when the substrate processing method described above was performed will be described with reference to FIG. 3. FIG. 3 is a diagram showing an example of the relationship between the microwave power and the number of particles during hydrogen modification according to one embodiment.

The process conditions of Experiment 1 are as follows.

### <Process Conditions for Precoated Film (SiN Film) in Experiment 1>

Types of gases: Silane gas, nitrogen gas or ammonia gas, helium gas
Pressure in the processing chamber: 6 Pa to 133 Pa
Microwave power (first power): 2,800 W

### <Process Conditions for Hydrogen Modification>

Types of gases: Hydrogen gas, argon gas
Pressure in the processing chamber: 2 Pa to 133 Pa
Microwave power (second power): 350 W to 3,500 W (horizontal axis of the graph in FIG. 3)

The horizontal axis of the graph in FIG. 3 indicates the second power, which is the microwave power during hydrogen modification, and the vertical axis indicates the number of particles during hydrogen modification. The number of particles shown in FIG. 3 indicates the number of products (such as precoated film fragments and the like) detected by scanning on the film surface of the substrate W.

According to the result of Experiment 1, the number of particles was small when the second power of the microwave applied during hydrogen modification was 350 W to 2,100 W. However, the number of particles started to increase around the second power of 2,100 W, and the number of particles was large in the second power range of 2,800 W to 3,500 W.

The first power of the microwave during formation of the precoated film was 2,800 W. Therefore, it was revealed that the number of particles became large when the first power of the microwave during formation of the precoated film was equal to or lower than the second power of the microwave during hydrogen modification. When the first power is equal to or lower than the second power, the precoated film tends to be damaged when hydrogen ions or the like in the plasma during hydrogen modification impinge on the precoated film, resulting in peeling of the precoated film. Therefore, it is considered that the number of particles increased as a result.

The higher the first power of the microwave during formation of the precoated film, the higher the density of the precoated film, and the stronger the film. Depending on the strength of the precoated film, the resistance of the precoated film against damage applied to the precoated film by hydrogen ions or the like during hydrogen modification changes. Therefore, hydrogen modification is performed using a microwave having a second power that is lower than the first power of the microwave during formation of the precoated film. For example, in the example shown in FIG. 3, as the first power applied during formation of the precoated film is 2,800 W, the second power applied during hydrogen modification is controlled to be lower than 2,800 W. Thus, it is possible to suppress particles when subjecting an SiN film formed on a substrate to hydrogen modification using a microwave plasma (hydrogen-containing plasma).

### [Result of Experiment 2]

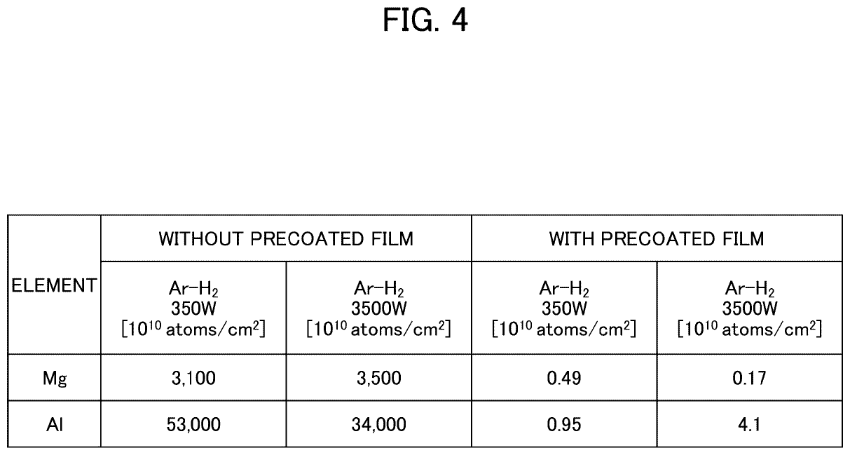

Next, the result of Experiment 2 showing the number of particles during hydrogen modification when the substrate processing method according to one embodiment (see FIG. 2) was performed and the number of particles during hydrogen modification when no precoated film was formed will be described with reference to FIG. 4. FIG. 4 is a diagram showing an example of the relationship between the microwave power and metal contaminations depending on presence or absence of formation of a precoated film according to one embodiment.

Metal contaminations shown in FIG. 4 are Inductively Coupled Plasma-Mass Spectrometry (ICP-Mass)-detected metal components as a result of dissolving the surface of the film on the substrate W during hydrogen modification, and are metal products on the substrate W.

The process conditions of Experiment 2 are as follows.

### <Process Conditions for Precoated Film (SiN Film) in Experiment 2>

Types of gases: Silane gas, nitrogen gas, ammonia gas, helium gas
Pressure in the processing chamber: 6 Pa to 133 Pa
Microwave power (first power): 2,800 W

### <Process Conditions for Hydrogen Modification>

Types of gases: Hydrogen gas, argon gas
Pressure in the processing chamber: 2 Pa to 133 Pa
Microwave power (second power): 350 W or 3,500 W

A metal contamination of 1×10¹⁰ (atoms/cm²) or less is tolerable. In the result of Experiment 2 shown in FIG. 4, when no precoated film was formed on the inner wall of the processing chamber 10, the amount of the metal contamination of aluminum (Al), which was a constituent of the inner wall of the processing chamber 10, during hydrogen modification was detected to be much higher than 1×10¹⁰ (atoms/cm²) both when the second power was 350 W and 3,500 W. Magnesium (Mg) is an impurity contained in Al, and the amount of the metal contamination of Mg was also detected to be much higher than 1×10¹⁰ atoms/cm². As a result, in the absence of the precoated film, it is considered that ions in the hydrogen-containing plasma impinged on and damaged the inner wall of the processing chamber 10, which generated metal contaminations that by far exceeded the tolerable range.

In the case where the precoated film was formed, the amounts of the metal contaminations of both aluminum and magnesium were detected to be less than 1×10¹⁰ atoms/cm² when the second power was 350 W. On the other hand, when the second power was 3,500 W, the amount of the metal contamination of magnesium was detected to be less than 1×10¹⁰ atoms/cm², but the amount of the metal contamination of aluminum was detected to be higher than 1×10¹⁰ atoms/cm².

Therefore, it was revealed that the precoated film had the function of protecting the processing chamber 10 from hydrogen ions, argon ions, and hydrogen radicals during hydrogen modification, and that metal contaminations could not be suppressed in the absence of the precoated film. Therefore, a dense film is preferable as the precoated film, and the film density is preferably 2.7 g/cm³ or greater when the precoated film is an SiN film.

As a result of Experiment 2, it was revealed that metal contaminations could be suppressed in the presence of the precoated film and at a lower second power of the microwave applied during hydrogen modification than the first power of the microwave applied during formation of the precoated film. On the other hand, it was revealed that even in the presence of the precoated film, metal contaminations could not be sufficiently suppressed when the second power of the microwave during hydrogen modification was higher than the first power of the microwave during formation of the precoated film.

### [Result of Experiment 3]

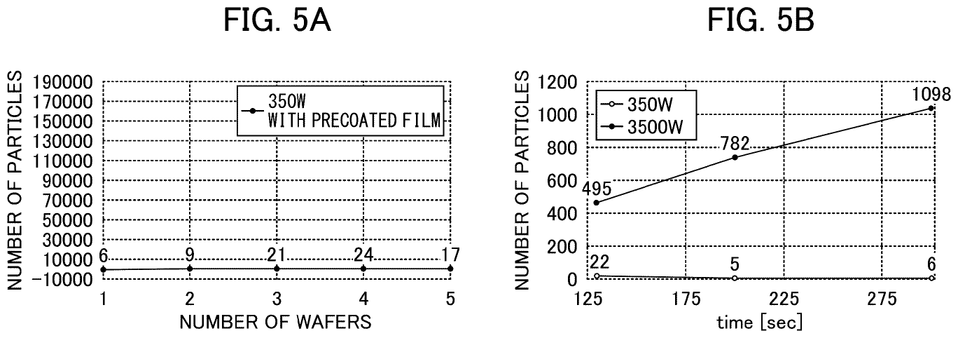

Next, the result of Experiment 3 showing the dependency of the number of particles during hydrogen modification on the number of substrates processed and on the processing time will be described with reference to FIGS. 5A and 5B. FIGS. 5A and 5B are diagrams showing an example of the dependency of the number of particles during hydrogen modification on the number of wafers processed and the dependency thereof on the processing time according to one embodiment.

The process conditions of Experiment 3 are as follows.

<Process Conditions for Precoated Film (SiN Film) in Experiment 3> are the same as the process conditions in Experiments 1 and 2, so description is omitted.

### <Process Conditions for Hydrogen Modification>

Types of gases: Hydrogen gas, argon gas
Pressure in the processing chamber: 2 Pa to 133 Pa
Microwave power (second power): 350 W or 3,500 W

FIG. 5A shows the dependency of the number of particles during hydrogen modification on the number of substrates processed. FIG. 5B shows the dependency of the number of particles during hydrogen modification on the number of substrates processed. In FIG. 5A, the horizontal axis represents the number of wafers (substrates W) processed by hydrogen modification, and the vertical axis represents the number of particles. In FIG. 5A, the second power of the microwave during hydrogen modification was 350 W, and a precoated film was formed in advance. The first power of the microwave during formation of the precoated film was 2,800 W. In FIG. 5B, the horizontal axis represents the processing time for hydrogen modification of a wafer (substrate W), and the vertical axis represents the number of particles. In FIG. 5B, the second power of the microwave during hydrogen modification was 350 W and 3,500 W, and a precoated film was formed in advance. The first power of the microwave during formation of the precoated film was 2,800 W.

As a result of Experiment 3, in both of the graphs in FIGS. 5A and 5B, when the second power was 350 W, the number of particles during hydrogen modification after formation of the precoated film was suppressed to approximately 20 or less. On the other hand, in the graph in FIG. 5B, when the second power was 3,500 W, the number of particles during hydrogen modification after formation of the precoated film increased from several hundred to approximately 1,000 as the processing time for hydrogen modification increased, and the number of particles could not be suppressed within the tolerable range.

From the above, when hydrogen modification was performed by controlling the microwave power to be the low power of 350 W, the number of particles did not increase so much even when the processing time and the number of wafers processed were increased. On the other hand, it was revealed that even in the presence of the precoated film, the number of particles could not be suppressed within the tolerable range when the second power of the microwave during hydrogen modification was equal to or higher than the first power of the microwave during formation of the precoated film. That is, when the second power of the microwave during hydrogen modification was lower than the first power of the microwave during formation of the precoated film, the number of particles could be suppressed within the tolerable range. In other words, the number of particles can be suppressed within the tolerable range when the first power of the microwave supplied during formation of the precoated film is equal to or higher than the second power of the microwave supplied during hydrogen modification.

### [Results of Experiment 4]

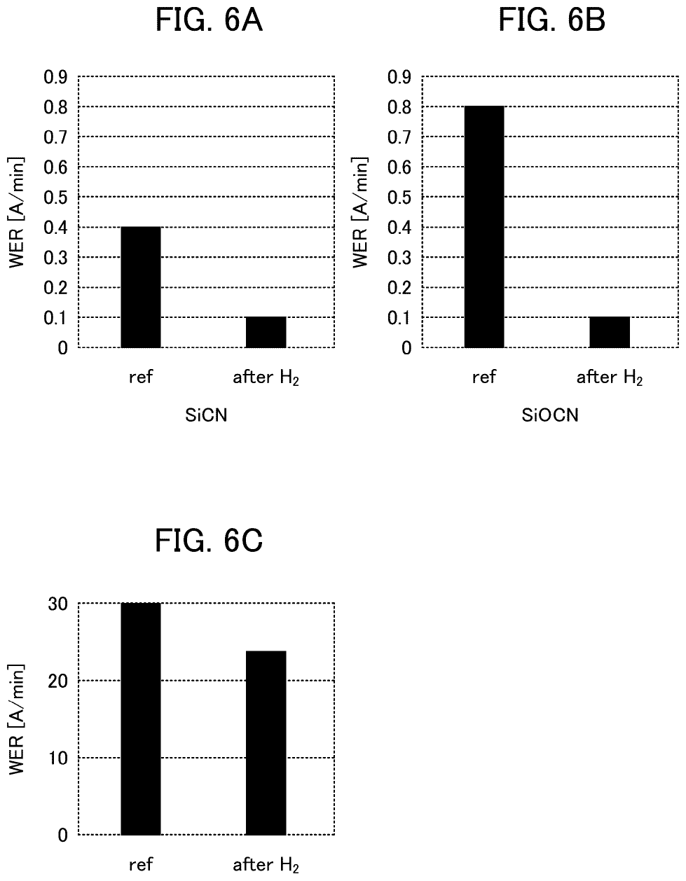

Next, the result of Experiment 4 showing the types of hydrogen modification target films and the effect of hydrogen modification will be described with reference to FIGS. 6A to 6C. FIGS. 6A to 6C are diagrams showing an example of a type of a hydrogen modification target film and the effect of hydrogen modification according to one embodiment.

The process conditions of Experiment 4 are as follows.

The process conditions for the precoated film (SiN film) in Experiment 4 are the same as the process conditions in Experiments 1 and 2, and description is omitted.

### <Process Conditions for Hydrogen Modification>

Types of gases: Hydrogen gas, argon gas
Pressure in the processing chamber: 2 Pa to 133 Pa
Microwave power (second power): 350 W
Modification target films: SiCN film, SiOCN film, SiN film

As the precoated film, an SiN film was formed. FIG. 6A shows the hydrofluoric acid resistance (WER) of the film before and after hydrogen modification, when the hydrogen modification target film formed on the substrate W was an SiCN film.

FIG. 6B shows the hydrofluoric acid resistance (WER) of the film before and after hydrogen modification, when the hydrogen modification target film formed on the substrate W was an SiOCN film. FIG. 6C shows the hydrofluoric acid resistance (WER) of the film before and after hydrogen modification, when the hydrogen modification target film formed on the substrate W was an SiN film. In each of FIGS. 6A to 6C, “ref” indicates the hydrofluoric acid resistance of the film before hydrogen modification, and “after H₂” indicates the hydrofluoric acid resistance of the film after hydrogen modification.

As a result of Experiment 4, in the case shown in FIG. 6A in which the hydrogen modification target film was a SiCN film, “ref” indicating the hydrofluoric acid resistance of the film before hydrogen modification was 0.4 Å/min, and “after H₂” indicating the hydrofluoric acid resistance of the film after hydrogen modification was 0.1 Å/min. Therefore, the hydrofluoric acid resistance of the SiCN film was improved by 75% through hydrogen modification.

In the case shown in FIG. 6B in which the hydrogen modification target film was an SiOCN film, “ref” indicating the hydrofluoric acid resistance of the film before hydrogen modification was 0.8 Å/min, and “after H₂” indicating the hydrofluoric acid resistance of the film after hydrogen modification was 0.1 Å/min. Therefore, the hydrofluoric acid resistance of the SiOCN film was improved by 87.5% through hydrogen modification.

In the case shown in FIG. 6C in which the hydrogen modification target film was an SiN film, “ref” indicating the hydrofluoric acid resistance of the film before hydrogen modification was 29.9 (Å/min), and “after H₂” indicating the hydrofluoric acid resistance of the film after hydrogen modification was 23.7 (Å/min). Therefore, the hydrofluoric acid resistance of the SiN film was improved by 21% through hydrogen modification.

The SiCN film and the SiOCN film are more easily invaded by impurities than the SiN film is, and have a greater difficulty than the SiN film in being formed as strong films. Therefore, their hydrofluoric acid resistance (WER), which is a film quality index, was better improved through hydrogen modification. However, the hydrofluoric acid resistance (WER) of the SiN film was also sufficiently improved through hydrogen modification.

As described above, according to the substrate processing method and the plasma processing apparatus 1 of the present embodiment, it was possible to suppress particles during hydrogen modification of a film formed on a substrate using a microwave plasma (hydrogen-containing plasma).

It has been described above that particles and metal contaminations can be suppressed when the second power of the microwave during hydrogen modification is lower than the first power of the microwave during formation of the precoated film. However, this is non-limiting.

When the plasma density during hydrogen modification is less than the plasma density during formation of the precoated film, particles and metal contaminations can be suppressed. In other words, the plasma density during formation of the precoated film is controlled to be equal to or greater than the plasma density during hydrogen modification. This makes it possible to form so strong a precoated film that generation of particles and metal contaminations can be suppressed even when the precoated film is impinged on by ions or the like in the hydrogen-containing plasma during hydrogen modification.

The plasma density varies depending not only on the microwave power but also on the pressure in the processing chamber 10 during hydrogen modification and the type of the gas used for hydrogen modification. However, the microwave power has the greatest effects on the plasma density.

Therefore, in the present embodiment, by adjusting the second power of the microwave during hydrogen modification to be lower than the first power of the microwave during formation of the precoated film, it is possible to control the plasma density during hydrogen modification to be lower than the plasma density during formation of the precoated film. Thus, it is possible to suppress particles and metal contaminations during hydrogen modification.

Furthermore, by controlling the pressure in the processing chamber 10 during formation of the precoated film and during hydrogen modification in addition to controlling the microwave power during formation of the precoated film and during hydrogen modification, it is possible to better suppress particles and metal contaminations during hydrogen modification. For example, by adjusting the pressure during hydrogen modification to be higher than the pressure during formation of the precoated film (by adjusting the pressure during hydrogen modification to be a high pressure), it is possible to reduce the plasma density during hydrogen modification, and to therefore better suppress particles and metal contaminations.

The substrate processing method and substrate processing apparatus according to the embodiments disclosed herein should be considered to be illustrative in all respects and not restrictive. Modifications and improvements in various forms are applicable to the embodiments without departing from the scope and spirit of the appended claims. The particulars described in the above plurality of embodiments can assume other configurations as long as no contradiction occurs, and can be combined as long as no contradiction occurs.

The substrate processing apparatus according to the present disclosure is preferably the plasma processing apparatus of FIG. 1 that is configured to form a microwave plasma. However, a plasma processing apparatus having a radial line slot antenna can also be applied as long as it is a plasma processing apparatus that can form a microwave plasma.

In the substrate processing apparatus of the present disclosure, not only hydrogen modification treatment but also film forming treatment, etching treatment, and the like may be performed. However, since a microwave plasma formed by the plasma processing apparatus 1 of FIG. 1 is a plasma having a low electron temperature but having a high electron density, a film (an SiN film and the like) to be formed on a substrate W by this apparatus will have a high film density, and it is predicted that there is a case where hydrogen modification treatment is not necessary for such a film. Therefore, in the plasma processing apparatus 1, hydrogen modification is mainly performed on a film having a relatively low film density, for example, a film having a low film density (e.g., a film having a density of 2.7 (g/cm³) or lower) that is formed on a substrate W by another apparatus, such as a CVD apparatus and the like. Thus, it is possible to modify the film by reducing the hydrogen content in the film, and to improve characteristics of the film, such as etching selectivity and the like.

According to one aspect of the present disclosure, it is possible to suppress particles when modifying a film formed on a substrate using a microwave plasma.

What is claimed is:

1. A substrate processing method for modifying a film formed on a substrate, the substrate processing method comprising:
forming a precoated film on a surface of a processing chamber by a plasma formed from a precoating gas using a microwave having a first power;
preparing the substrate on a mounting table in the processing chamber; and
modifying the film formed on the substrate by irradiating the film with a hydrogen-containing plasma formed from a hydrogen-containing gas using a microwave having a second power that is lower than the first power.

2. The substrate processing method according to claim 1,
wherein the film is a silicon-containing film.

3. The substrate processing method according to claim 1,
wherein the precoating gas contains a silicon raw material gas and a reactive gas reacting with the silicon raw material gas, and
wherein the precoated film is formed by exposing the surface of the processing chamber to the plasma that is formed by supplying the silicon raw material gas and the reactive gas.

4. The substrate processing method according to claim 1,
wherein the precoated film is an SiN film.

5. The substrate processing method according to claim 1,
wherein the film is any one of an SiN film, an SiCN film, an SiOCN film, an SiON film, an SiO₂ film, a silicon film, or a carbon film.

6. The substrate processing method according to claim 1,
wherein the first power is in a range of 2,000 W to 6,000 W, and the second power is in a range of 100 W to 4,000 W and is lower than the first power.

7. The substrate processing method according to claim 1,
wherein the hydrogen-containing gas contains: either or both of hydrogen gas and ammonia gas; and an inert gas.

8. The substrate processing method according to claim 1,
wherein in the forming of the precoated film, a pressure in the processing chamber is 6 Pa to 133 Pa.

9. The substrate processing method according to claim 1,
wherein in the modifying of the film, a pressure in the processing chamber is 2 Pa to 133 Pa.

10. The substrate processing method according to claim 1,
wherein the film is formed on the substrate by using any of plasma CVD, thermal CVD, plasma ALD, or thermal ALD.

11. The substrate processing method according to claim 1,
wherein the forming of the precoated film is performed when a number of substrates on which the modifying of the film has been performed has exceeded a predetermined number, and the forming of the precoated film is performed after an interior of the processing chamber is cleaned.

12. A substrate processing apparatus, comprising:
a processing chamber;
a mounting table situated in the processing chamber;
a top wall facing the mounting table;
a microwave generation source configured to generate a microwave, and situated on the top wall;
a side wall of the processing chamber;
a gas supply situated on the top wall; and
a controller,
wherein the controller is configured to control:
forming of a precoated film on a surface of the processing chamber by a plasma, by forming the plasma from a precoating gas by supplying the precoating gas from the gas supply while supplying a microwave having a first power from the microwave generation source;
preparing of a substrate on the mounting table; and
modifying of a film formed on the substrate, by irradiating the film formed on the substrate with a hydrogen-containing plasma, by forming the hydrogen-containing plasma from a hydrogen-containing gas by supplying the hydrogen-containing gas from the gas supply while supplying a microwave having a second power that is lower than the first power from the microwave generation source.
